(19) United States
(12) Patent Application Publication
(10) Pub. No.: US 2012/0273796 A1
(43) Pub. Date: Nov. 1, 2012

(54) HIGH INDIUM UPTAKE AND HIGH POLARIZATION RATIO FOR GROUP-III NITRIDE OPTOELECTRONIC DEVICES FABRICATED ON A SEMIPOLAR (20-2-1) PLANE OF A GALLIUM NITRIDE SUBSTRATE

(75) Inventors: Yuji Zhao, Goleta, CA (US); Shinichi Tanaka, Santa Barbara, CA (US); Chia-Yen Huang, Goleta, CA (US); Daniel F. Feezell, Santa Barbara, CA (US); James S. Speck, Goleta, CA (US); Steven P. DenBaars, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/459,963

(22) Filed: Apr. 30, 2012

Related U.S. Application Data
(60) Provisional application No. 61/480,968, filed on Apr. 29, 2011.

(51) Int. Cl. H01L 33/00

(52) U.S. Cl. 257/76; 438/46; 257/E33.023

(57) ABSTRACT

A Group-III nitride optoelectronic device fabricated on a semipolar (20-2-1) plane of a Gallium Nitride (GaN) substrate is characterized by a high Indium uptake and a high polarization ratio.

### CROSS-REFERENCE TO RELATED APPLICATIONS

This application claims the benefit under 35 U.S.C. Section 119(e) of co-pending and commonly-assigned U.S. Provisional Patent Application Ser. No. 61/480,968, filed on Apr. 29, 2011, by Yuji Zhao, Shinichi Tanaka, Chia-Yen Huang, Daniel F. Feezell, James S. Speck, Steven P. DenBaars, and Shuji Nakamura, entitled “HIGH INDIUM UPTAKES AND HIGH POLARIZATION RATIO ON GALLIUM NITRIDE SEMIPOLAR (20-2-1) SUBSTRATES FOR III-NITRIDE OPTOELECTRONIC DEVICES,” attorneys' docket number 30794.411-US-P1 (2011-580-1), which application is incorporated by reference herein.

### BACKGROUND OF THE INVENTION

1. Field of the Invention

The invention is related generally to the field of optoelectronic devices, and more particularly, to Group-III nitride light emitting devices fabricated on a semipolar (20-2-1) plane of a Gallium Nitride (GaN) substrate, wherein the devices are characterized by a high Indium uptake and a high polarization ratio.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Existing Group-III nitride optoelectronic devices are typically grown on polar {0001}, nonpolar {10−10} and {11-20}, or semipolar {11-22} and {10−1-1} planes. The shaded surfaces in FIG. 1 provide examples of polar, nonpolar and semipolar orientations in a wurtzite Group-III nitride crystal.

Semipolar and nonpolar (m-plane or a-plane) orientations of Group III nitrides have attracted considerable attention for realizing high-efficiency light-emitting diodes (LEDs) [1] and laser diodes (LDs) [2]. Several advantages of semipolar and nonpolar structures over commercially available polar (c-plane) structures have been highlighted, including reduced polarization-induced electric fields in the quantum wells (QWs) [3-5], increased Indium uptake [6-8] and polarized light emission [9-11].

The former characteristics of reduced polarization and increased Indium uptake are promising for achieving high-performance green light emitters, while the latter characteristic of polarized light emission contributes to anisotropic optical gain in LDs fabricated on these planes [12]. For example, on nonpolar (m-plane), the emission components polarized along the a- and c-axes involve the highest and second highest valence bands, respectively. Due to the higher emission intensity along the a-axis [13], LD stripes oriented along the c-axis exhibit a lower threshold current and thus are preferred for m-plane LDs [14]. The relative magnitude of the intensity parallel to and perpendicular to the c-axis is described by the polarization ratio and high values are preferred for improved LD performance. Similar optical gain and threshold behavior have also been observed on semipolar {11-22} [15-16] and (20-21) devices [17].

While high polarization ratios have been reported for m-plane devices [18-19], long wavelength emission is difficult to achieve on this plane due to the generation of defects at high Indium compositions. On the other hand, the semipolar (20-21) orientation has shown promising performance at long wavelengths, but the reported polarization ratios are relatively low [17].

Thus, there is a need in the art for improved methods of fabricating Group-III nitride optoelectronic devices on a semipolar orientations. The present invention satisfies this need.

### SUMMARY OF THE INVENTION

To overcome the limitations in the prior art described above, and to overcome other limitations that will become apparent upon reading and understanding the present specification, the present invention discloses Group-III nitride optoelectronic devices fabricated on a semipolar (20-2-1) plane of a GaN substrate that are characterized by a high Indium uptake and a high polarization ratio. An optoelectronic device grown on a semipolar (20-2-1) plane of a GaN substrate, which is a semipolar plane comprised of a miscut from the m-plane in the c-direction, has minimal polarization related electric fields as compared to other semipolar planes (i.e., {11-22}, {10-1-1}, etc.). Moreover, an optoelectronic device grown on a semipolar (20-2-1) plane of a GaN substrates has a lower QCSE (quantum confined Stark effect) induced, injection current dependent, blue shift in its output wavelength, as well as increased oscillator strength, leading to higher material gain, etc., as compared to, for example, c-plane devices and other nonpolar or semipolar devices. In addition, an optoelectronic device grown on a semipolar (20-2-1) plane of a GaN substrates is likely to show better performance at long wavelengths, since semi-polar planes are believed to incorporate Indium more easily.

### BRIEF DESCRIPTION OF THE DRAWINGS

Referring now to the drawings in which like reference numbers represent corresponding parts throughout:

FIG. 1 includes schematics of a wurtzite Group-III nitride crystal, wherein shaded surfaces provide examples of polar, nonpolar and semipolar orientations in the crystal.

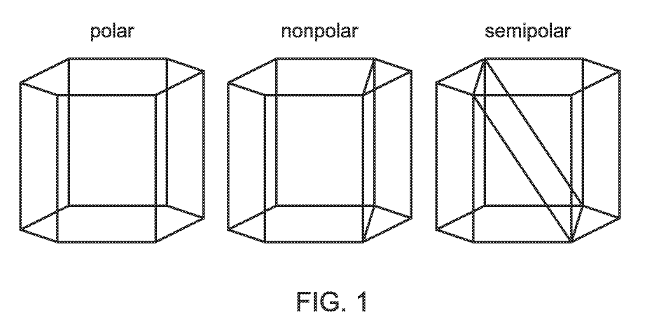

FIG. 2 is a schematic of the atomic structure of a wurtzite Group-III nitride crystal showing different crystal planes of (20-21), (20-2-1) and m-plane (10-10) in the crystal structure.

FIG. 3 is a schematic illustrating an exemplary device structure according to one embodiment of the present invention.

FIG. 4 is a flowchart illustrating an exemplary process for fabricating the exemplary device structure of FIG. 3.

FIG. 5 is a graph of temperature vs. wavelength for a trimethylindium (TMI) flow for (20-2-1) and (20-21) LEDs grown under the same growth conditions.

FIG. 6(a) is a graph of wavelength vs. polarization ratio for LEDs grown on (20-2-1), (20-21) and m-plane surfaces, with annotations to the corresponding references.

FIG. 6(b) is a graph of current density vs. polarization ratio for LEDs grown on (20-2-1) GaN substrates.

FIGS. 7(a) and 7(b) are graphs of wavelength vs. electroluminesence (EL) intensity of (20-2-1) LEDs.

FIG. 7(c) is a graph of wavelength vs. energy separation (ΔE) for (20-2-1), (10-10) and (20-21) devices.

FIG. 8 is a graph of wavelength vs. electroluminesence (EL) intensity for (20-2-1) and (20-21) devices.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention discloses Group-III nitride based optoelectronic devices grown on a semipolar (20-2-1) plane of a GaN substrate, which is a miscut from the m-plane in the c-direction. Such devices are referred to herein as (20-2-1) devices, and are characterized by a high Indium uptake and a high polarization ratio.

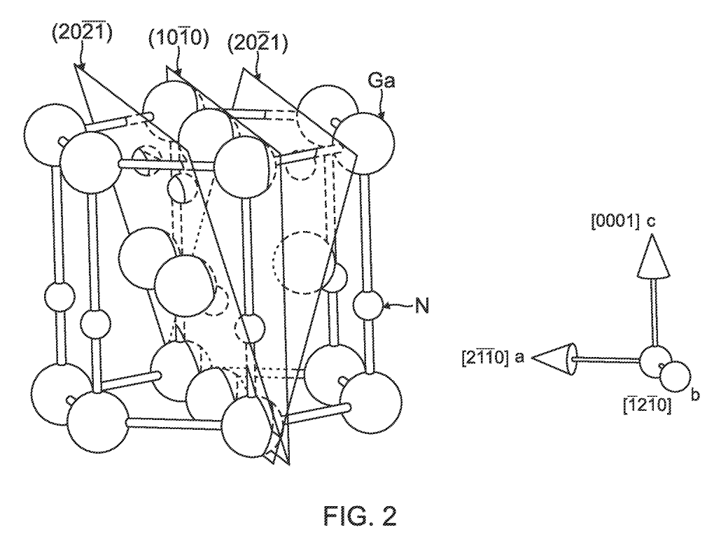

The semipolar (20-2-1) plane of the GaN substrate is inclined at approximately 15° towards the [000-1] direction from the nonpolar (m-plane) (10-10) plane and is inclined at approximately 30° towards the [000-1] direction from the semipolar (20-21) plane. Schematic views of the different crystal planes of (20-21), (20-2-1) and m-plane (10-10) in a wurtzite crystal structure are shown in FIG. 2.

Products incorporating the present invention would include various (20-2-1) optoelectronic devices, such as light-emitting diodes (LEDs), laser diodes (LDs), solar cells, etc., for display applications, lighting, illumination, water purification, energy applications, etc.

Device Structure

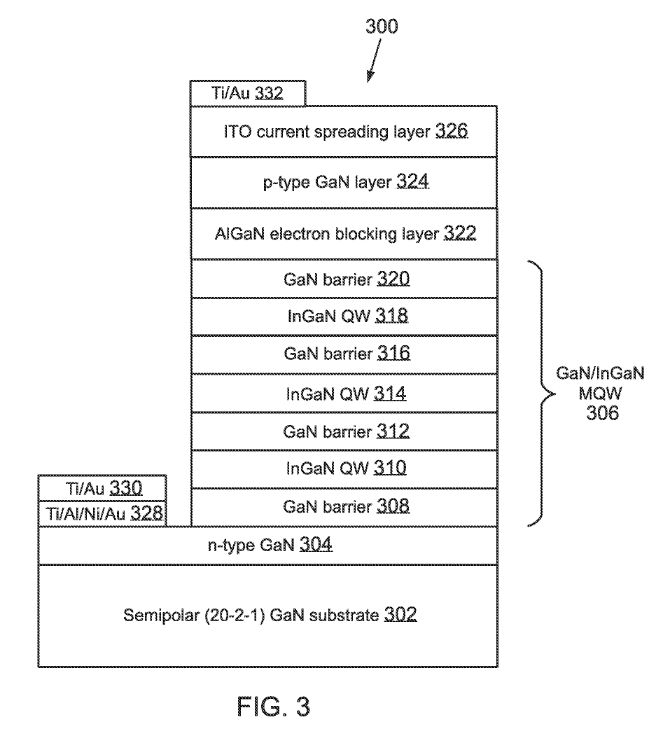

FIG. 3 is a schematic illustrating an exemplary device structure according to one embodiment of the present invention. The exemplary device structure comprises an LED 300, wherein the LED epitaxial layers were homoepitaxially grown by conventional MOCVD on a free-standing (20-2-1) GaN substrate 302 supplied by Mitsubishi Chemical Corporation. The LED epitaxial layers include a 1 μm Si-doped n-type GaN layer 304, a multiple quantum well (MQW) structure 306 comprised of three periods of GaN/InGaN with 13 nm GaN barriers and 3 nm InGaN QWs, namely, a GaN barrier 308, an InGaN QW 310, a GaN barrier 312, an InGaN QW 314, a GaN barrier 316, an InGaN QW 318, and a GaN barrier 320, a 16 nm Mg-doped p-type Al_{0.15}Ga_{0.85}N electron blocking layer (EBL) 322, and a 60 nm p-type GaN layer 324. For the LED fabrication, a rectangular mesa pattern (490×292 μm²) was formed by conventional lithography and chlorine-based inductively coupled plasma (ICP) etching after an indium tin oxide (ITO) current spreading layer 326 was deposited by electron beam evaporation. A Ti/Al/Ni/Au n-type contact 328 and Ti/Au pads 330, 332 were deposited by electron beam evaporation and a conventional lift-off process. After that, black ink (not shown) was applied to bottom and side surface of the devices as a photon absorbing element.

Process Steps

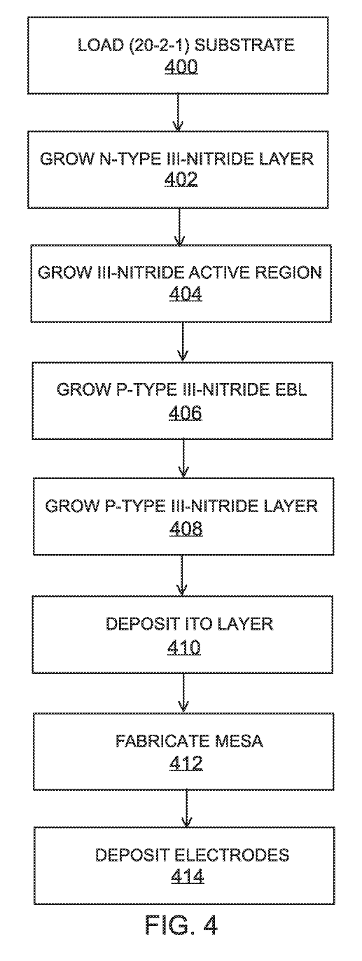

FIG. 4 is a flowchart illustrating an exemplary process for fabricating the exemplary device structure of FIG. 3.

Block 400 represents a semipolar (20-2-1) substrate being loaded into a metal organic chemical vapor deposition (MOCVD) reactor. The semipolar (20-2-1) substrate can be a bulk Group-III nitride or a film of Group-III nitride.

Block 402 represents the growth of an n-type Group-III nitride layer, e.g., Si doped n-GaN, on the substrate.

Block 404 represents the growth of a Group-III nitride active region, e.g., a 3× InGaN/GaN MQW structure, on the n-GaN layer.

Block 406 represents the growth of a p-type Group-III nitride EBL, e.g., Mg doped p-AlGaN, on the active region.

Block 408 represents the growth of a p-type Group-III nitride layer, e.g., Mg doped p-GaN, on the p-AlGaN EBL.

Block 410 represents the deposition of a transparent conducting oxide (TCO) layer, such as indium-tin-oxide (ITO), as a current spreading layer on the p-GaN layer.

Block 412 represents the fabrication of a mesa by patterning and etching.

Block 414 represents the deposition of a Ti/Al/Ni/Au layer on the n-GaN layer exposed by the mesa etch, followed by the deposition of electrodes, such as Ti/Au, on the Ti/Al/Ni/Au layer and on the ITO layer.

Other steps not shown in FIG. 4 may also be performed, such as activation, annealing, dicing, mounting, bonding, encapsulating, packaging, etc.

The end result of these process steps is an optoelectronic device comprising a Group-III nitride LED grown on a semipolar (20-2-1) plane of a Group-III nitride substrate.

Experimental Results

The following describes the results of experiments performed by the inventors on the semipolar (20-2-1) Group-III nitride LEDs of the present invention. Semipolar (20-21) LEDs with the same device structure were also fabricated as reference samples for these experiments.

The polarization of spontaneous emission was investigated by electroluminescence (EL) measurement for semipolar (20-2-1) InGaN/GaN LEDs covering the blue to green spectral range. The EL measurements were carried out under DC operation at room temperature using a 0.45 numerical aperture 20× objective designed for collection of polarized light.

The optical polarization ratio (ρ) is defined as:

ρ=(I_{[-12-10]}−I_{[-101-4]})/(I_{[-12-10]}+I_{[-101-4]})

where I_{[-12-10]} and I_{[-101-4]} are the integrated intensity values from the EL spectrum, and the energy separation (ΔE) is characterized as the peak energy difference between the two polarized emissions. The details of the experimental setup can be found in [20].

Using integrated EL measurements, the polarization ratio was measured as 0.46 at a wavelength of 418 nm and 0.67 at 519 nm for 490×292 μm²(20-2-1) devices at 20 mA, while comparable (20-21) devices of a similar wavelength showed a much lower polarization ratio of 0.34 and 0.47.

The valance band energy separation results were consistent with the polarization ratio results. X-Ray Diffraction (XRD) results on the InGaN/GaN MQW superlattice indicate that the (20-2-1) plane takes up twice as much Indium as compared to the (20-21) plane under similar growth conditions. These results suggest that (20-2-1) devices have the potential to achieve high performance in a longer spectral region.

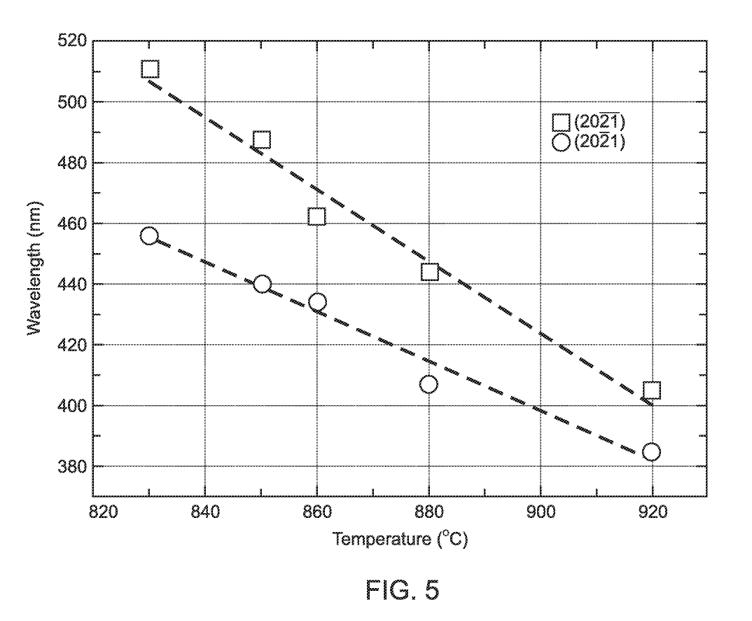

FIG. 5 is a graph of wavelength vs. temperature for a trimethylindium (TMI) flow for (20-2-1) and (20-21) LEDs grown under the same growth conditions. Growth on the semipolar (20-2-1) plane showed higher Indium uptakes as compared to devices grown on the semipolar (20-21) plane, indicating that the semipolar (20-2-1) plane is more suitable for longer wavelength devices. For example, prototypes of (20-2-1) blue and green LEDs demonstrated a longer wavelength, on the order of approximately 20-30 nm longer, than (20-21) devices fabricated under the same growth conditions. Moreover, higher Indium uptakes also mean that (20-2-1) devices can be grown at higher temperatures and have better crystal quality.

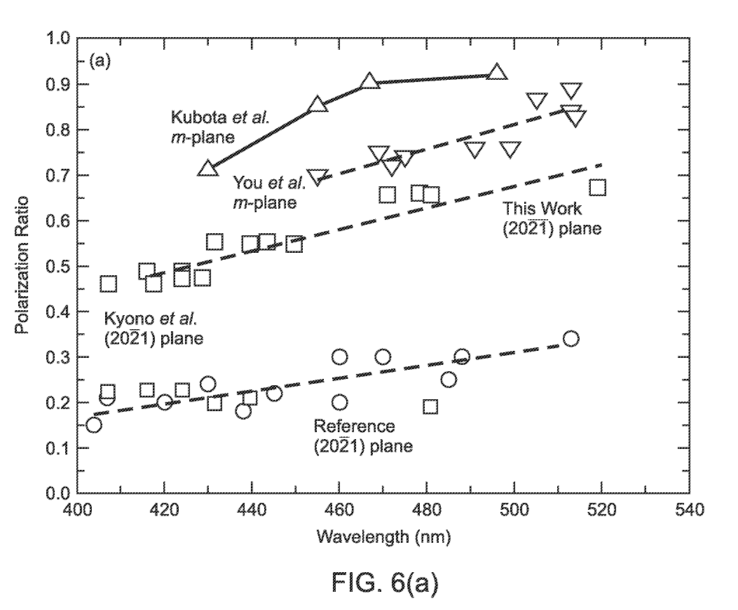

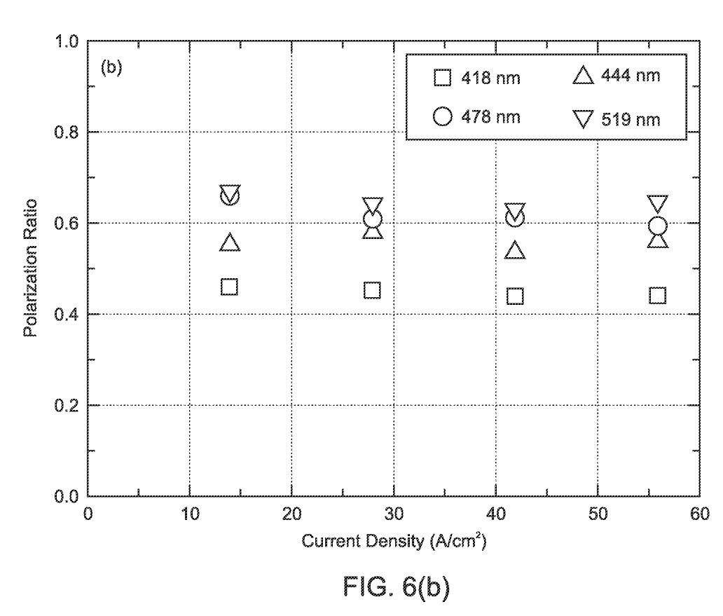

FIG. 6(a) is a graph of polarization ratio vs. wavelength for LEDs grown on (20-2-1), (20-21) and m-plane surfaces, with annotations to the corresponding references set forth below. The reported polarization data for MQWs with a 3-4 nm well thickness on m-planes [11,18] obtained by photoluminescence (PL) and for MQWs with 3-4 nm wells on semipolar (20-21) planes [17] measured under a current density of 7.4 A/cm², and for reference (20-21) samples that were grown, fabricated and measured under same conditions, are also plotted in FIG. 6(a). The graph shows that devices grown on a semipolar (20-2-1) plane exhibit a higher optical polarization ratio than devices grown on the semipolar (20-21) plane and the nonpolar m-plane {10-10}. A higher optical polarization ratio will result in devices with higher optical gain and lower threshold current.

FIG. 6(b) illustrates the ρ as a function of different current densities, varied from 10.5 A/cm² to 55.9 A/cm². The polarization ratio is nearly independent of electrical bias, possibly indicating a good compositional uniformity of the (20-2-1) InGaN QWs.

The results for the (20-21) reference samples are very close to previous reported data, indicating that errors caused by different experiment setups can be minimized. The polarization ratio on (20-2-1) monotonically increases with the wavelength, which is in agreement with theoretical results. While this peak wavelength dependence was similar to that for m-plane (10-10) and the (20-21) plane, the (20-2-1) devices show a much larger value of ρ than (20-21) devices. It has been theoretically predicted and also experimentally proved that a high polarization ratio is preferable to enhance optical gain. These results indicate that the (20-2-1) devices would be effective to further increase optical gain in the green spectral region. It is also expected that (20-2-1) LDs will have a reduced threshold current as compared to (20-21) devices.

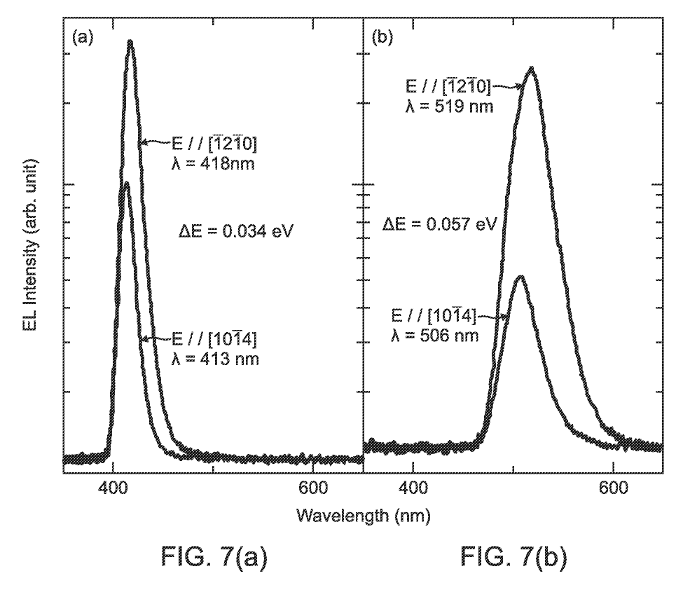

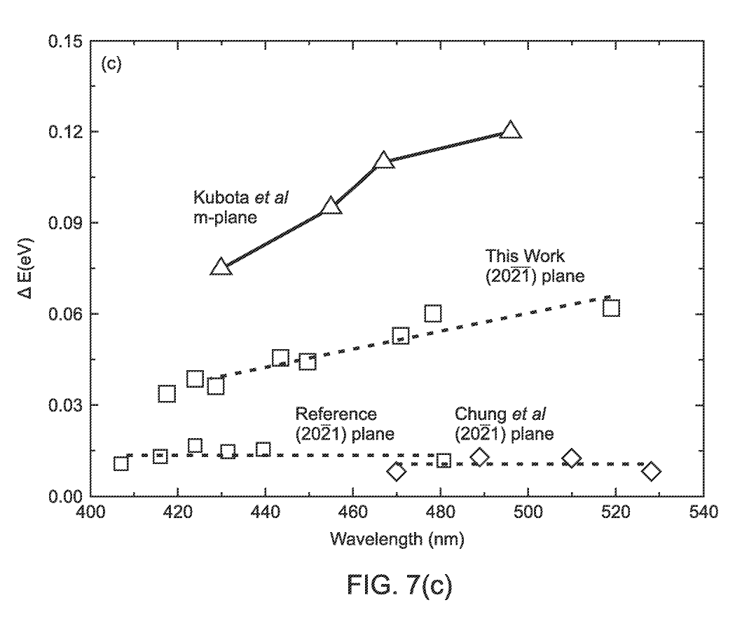

FIGS. 7(a) and 7(b) illustrate the EL spectra of (20-2-1) LEDs at a wavelength of 418 nm and 519 nm, respectively, in which the emission components are polarized along the [−12-10] dominants by showing a higher intensity peak than that of emission components polarized along [−101-4]. It is clear that intensity difference between the two components becomes larger as the wavelength increases, which is in good agreement with the theory. It is also noteworthy that the switching phenomenon that was reported for (11-22) InGaN QWs [21,22] was not observed in the (20-2-1) devices, as well as the (20-21) devices.

FIG. 7(c) demonstrates the energy separation (ΔE) with an increasing wavelength on (20-2-1) devices, while reported values on m-plane (10-10) [11] and (20-21) devices [23], and data on reference (20-21) devices, are plotted as well. All the data show an increasing ΔE with increasing wavelength, which is in good agreement with the theoretical results. It is anticipated that, by incorporating more Indium in the QWs, the in-plane anisotropic strain increases and further splits the valence bands. The (20-2-1) devices show a higher degree of band splitting as compared to (20-21) devices, which is consistent with polarization ratio results.

It is widely believed that the optical anisotropy of nonpolar and semipolar planes is due to the low crystal symmetries and unbalanced biaxial stress inside the QWs, which splits the uppermost valance band. Ideally, the stress conditions should be the same for the (20-21) and (20-2-1) planes, since they are both 15 degrees towards the m-plane and thus symmetric to each other. In reality, however, different growth mechanisms and surface chemistry of these two planes may lead to other situations, such as partial strain relaxation, which has been experimentally observed [24], and theoretically predicted [25] to have effect in polarization switch phenomenon on the semipolar (11-22) plane. Experiments are currently being carried out to investigate the critical thickness of InGaN film on both planes, which will lead to a better understanding of stress conditions on these two planes. On the other hand, the fact that the (20-2-1) and (20-21) planes have opposite signs of both piezoelectric and spontaneous polarization inside the QWs may also play a role, since it may cause effects, such as band filling, which will affect devices' optical performance.

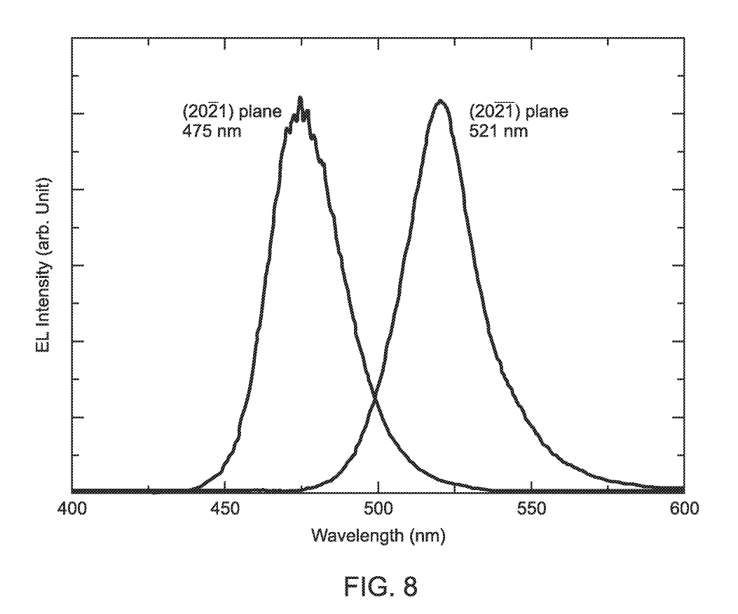

To further examine the differences between the (20-2-1) and (20-21) planes, a series of co-load experiments have been carried out. FIG. 8 demonstrates the normalized EL intensity of two LEDs on both planes that are co-loaded under the same growth condition. The (20-2-1) devices showed a longer wavelength (521 nm) as compared to the shorter wavelength (475 nm) of the (20-21) devices, indicating a higher Indium composition inside the QWs.

A second group of samples with 15 pairs of InGaN/GaN in a superlattice structure were grown on (20-2-1), (20-21) and m-plane (10-10) by the co-load experiment and characterized by XRD analysis. The growth rates of GaN, InGaN and the indium composition of each sample are summarized in Table 1 below:

TABLE 1
Growth rate of GaN, InGaN and the Indium composition
for co-loaded m-plane (10-10), (20-21) and (20-
2-1) InGaN/GaN superlattice growths.

| Substrate orientations | GR_{GaN} (Å/s) | GR_{InGaN} (Å/s) | In comp (%) |
|---|---|---|---|
| (10-10) m-plane | 0.46 | 0.49 | 2.7 |
| (20-21) | 0.39 | 0.56 | 3.3 |
| (20-2-1) | 0.43 | 0.51 | 6.5 |

While the growth rate of GaN and InGaN are very close for all three planes, the Indium composition on (20-2-1) (6.5%) plane was found to be almost twice of that of the (20-2-1) plane (3.3%), and also higher than the (10-10) m-plane (2.7%). Since Indium incorporation on GaN strongly depends on growth temperature, it is expected that (20-2-1) devices can be grown at least 40-50 degrees higher than (20-21) devices to achieve the same wavelength. The inventors' initial study also suggests that the wavelength spectrum of a green LED at 515 nm on the (20-2-1) plane has a smaller Full-Width-at-Half-Maximum (FWHM) (28 nm) than the FWHM (40 nm) of an LED on the (20-21) plane at the same wavelength, which may be an indication of good crystal quality or less Indium fluctuation due to higher growth temperature.

The origin of the different Indium incorporation for different semipolar planes is a topic of on-going discussion. It has been observed that a semipolar plane that is Nitrogen face (N-face) has higher Indium uptakes than that of Gallium face (Ga-face) planes [26], which is believed to associate with dangling bond and surface reconstructions on different planes. However, since highly inclined semipolar planes have high densities of step edges, further analysis and systematic studies are required to clearly explain the phenomenon.

In summary, the inventors' results indicate that devices fabricated on the (20-2-1) plane have higher optical polarization ratio, higher Indium composition and smaller FWHM than (20-21) devices, all of which characteristics are favorable for the fabrication of high performance optoelectronic devices emitting in green and longer wavelength regions, such as green LDs fabricated on the (20-2-1) plane.

### ADVANTAGES AND IMPROVEMENTS

Advantages and improvements resulting from optoelectronic device structures grown on a semipolar (20-2-1) crystal plane of a GaN substrate include the following properties:
higher Indium uptakes,
higher polarization ratio,
higher optical gain,
low threshold current,
higher growth temperature, and
better crystal quality,
   as compared to as compared to devices grown on polar, nonpolar or other semipolar planes.

Possible Modifications and Variations

Possible modifications and variations include different optoelectronic device structures, including the following:
Group-III nitride LEDs fabricated on a semipolar (20-2-1) plane of a GaN substrate may have different wavelength structures, which can cover a large range of spectrum, from deep UV (˜200 nm) to red (˜650 nm).
Devices on such miscuts as the semipolar (20-2-1) plane of a GaN substrate can include laser diodes, superluminescent diodes, semiconductor amplifiers, photonic crystal lasers, VCSEL lasers, solar cells, and photodetectors.
Laser diode devices on such miscuts may have etched facet mirrors or laser ablated facet mirrors whenever cleaved facet mirrors are not possible.
Laser diode devices on such miscuts may have cleaved facet mirrors with tilted facets or facets perpendicular to the growth plane.
Laser diode devices on such miscuts may have waveguides oriented in the c-projection direction for higher gain.
Laser diode devices on such miscuts could employ optical feedback from cavity mirrors/facets and/or DBR/gratings, etc.
Laser diode devices on such miscuts could employ optical gain (i.e., superluminescent diodes (SLD) or semiconductor optical amplifiers).
Laser diode devices on such miscuts could employ different waveguide structures.
Laser diode devices on such miscuts can have one or two angled facets or rough facets (formed by wet chemical etching) to suppress feedback in, for example, an SLD.
Laser diode devices on such miscuts could have passive cavities or saturable absorbers.
LED devices on such planes as the semipolar (20-2-1) plane of a GaN substrate may have different high light extraction designs, such as surface roughening via dry etching, photoelectrochemical (PEC) wet etching, photonic crystal structure, etc.
LED devices on such planes may have non-conventional structures, such as vertical structures, flip chip structures, thin GaN structures, etc.
LED devices on such planes may have a low droop designed active region, such as multiple quantum wells, InGaN barriers, AlGaN barriers, AlInGaN barriers, barriers with varied growth temperate, etc.
LED devices on such planes could employ special electron blocking layers (EBLs) such as InN, AlInN, superlattice EBLs, etc.
LED devices on such planes could employ wafer bonding techniques.
LED devices on such planes could employ different p-contact structures, such as ITO, highly reflective Ag based p-contacts (flip-chip), Ni/Ag, etc.
LED devices on such planes could employ different package methods, such as conventional packages, suspended packages, transparent stand packages, etc.

Other possible modifications and variations include different epitaxial growth techniques (MBE, MOCVD, etc.), different dry-etching techniques (ICP/RIE/FIB/CMP/CAIBE), and different packaging techniques.

In the future, it is envisioned that there will be various improvements to device performance, continuous-wave (CW) operation for LEDs and LDs, increased working wavelengths, increased light output power and external quantum efficiency, increased polarization ratio, increased optical gain, and decreased threshold current, for (20-2-1) devices.

Nomenclature

The terms “Group-III nitride”, “III-nitride,” or “nitride,” as used herein refer to any alloy composition of the (Ga, Al, In, B)N semiconductors having the formula Ga_{w}AlₓIn_{y}B_{z}N where 0≦w≦1, 0≦x≦1, 0≦y≦1, 0≦z≦1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga, Al, In, B)N material species. Further, (Ga, Al, In, B)N materials within the scope of the invention may further include minor quantities of dopants and/or other impurity or inclusional materials.

Many (Ga, Al, In, B)N devices are grown along a polar orientation, namely a c-plane of the crystal, although this results in an undesirable quantum-confined Stark effect (QCSE), due to the existence of strong piezoelectric and spontaneous polarizations. One approach to decreasing polarization effects in (Ga, Al, In, B)N devices is to grow the devices along nonpolar or semipolar orientations of the crystal.

The term “nonpolar plane” includes the {11-20} planes, known collectively as a-planes, and the {10-10} planes, known collectively as m-planes. Such planes contain equal numbers of gallium and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

When identifying orientations using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

### REFERENCES

The following references are incorporated by reference herein:
[1] Y. Zhao, J. Sonoda, C. C. Pan, S. Brinkley, I. Koslow, K. Fujito, H. Ohta, S. P. DenBaars, and S. Nakamura, Appl. Phys. Express 3, 102101 (2010).
[2] J. W. Raring, M. C. Schmidt, C. Poblenz, Y. C. Chang, M. J. Mondry, B. Li, J. Iveland, B. Walters, M. R. Krames, R. Craig, P. Rudy, J. S. Speck, S. P. DenBaars, and S. Nakamura, Appl. Phys. Express 3, 112101 (2010).
[3] P. Waltereit, O. Brandt, A. Trampert, H. T. Grahn, J. Menniger, M. Ramsteiner, M. Reiche, and K. H. Ploog, Nature (London) 406, 865 (2000).
[4] M. C. Schmidt, K. C. Kim, H. Sato, N. Fellows, H. Masui, S. Nakamura, S. P. DenBaars, and J. S. Speck, Jpn. J. Appl. Phys. 46, L126 (2007).
[5] Y. Zhao, J. Sonoda, I. Koslow, C. C. Pan, H. Ohta, J. S. Ha, S. P. Denbaars, and S. Nakamura, Jpn. J. Appl. Phys. 49, 070206 (2010).
[6] Y. Enya, Y. Yoshizumi, T. Kyono, K. Akita, M. Ueno, M. Adachi, T. Sumitomo, S. Tokuyama, T. Ikegami, K. Katayama, and T. Nakamura, Appl. Phys. Express 2, 082101 (2009).
[7] Y. D. Lin, S. Yamamoto, C. Y. Huang, C. L. Hsiung, F. Wu, K. Fujito, H. Ohta, J. S. Speck, S. P. Denbaars, and S. Nakamura, Appl. Phys. Express 3, 082001 (2010).
[8] S. Yamamoto, Y. Zhao, C. C. Pan, R. B. Chung, K. Fujito, J. Sonoda, S. P. Denbaars, and S. Nakamura, Appl. Phys. Express 3, 122102 (2010).
[9] N. F. Gardner, J. C. Kim, J. J. Wierer, Y. C. Shen, and M. R. Krames, Appl. Phys. Lett. 86, 111101 (2005).
[10] H. Masui, H. Yamada, K. Iso, S. Nakamura, and S. P. Denbaars, Appl. Phys. Lett. 92, 091105 (2008).
[11] M. Kubota, K. Okamoto, T. Tanaka, and H. Ohta, Appl. Phys. Lett. 92, 011920 (2008).
[12] S. H. Park and D. Ahn, Appl. Phys. Lett. 90, 013505 (2007).
[13] T. Ohtoshi, A. Niwa, and T. Kuroda, J. Appl. Phys. 82, 1518 (1997).
[14] K. Okamoto, H. Ohta, S. F. Chichibu, J. Ichihara, and H. Takasu, Jpn. J. Appl. Phys. 46, L187 (2007).
[15] K. Kojima, M. Funato, Y. Kawakami, S. Masui, S. Nagahama, and T. Mukai, Appl. Phys. Lett. 91, 251107 (2007).
[16] A. Tyagi, Y. D. Lin, D. A. Cohen, M. Saito, K. Fujito, J. S. Speck, S. P. DenBaars, and S. Nakamura, Appl. Physics Express 1, 091103 (2008).
[17] T. Kyono, Y. Yoshizumi, Y. Enya, M. Adachi, S. Tokuyama, M. Ueno, K. Katayama, and T. Nakamura, Appl. Physics Express 3, 011003 (2010).
[18] S. You, T. Detchprohm, M. Zhu, W. Hou, E. A. Preble, D. Hanser, T. Paskova, and C. Wetzel, Appl. Physics Express 3, 102103 (2010).
[19] S. Brinkley, Y. D. Lin, A. Chakraborty, N. Pfaff, D. Cohen, J. S. Speck, S. P. Denbaars, and S. Nakamura, Appl. Phys. Lett. 98, 0111101 (2011).
[20] H. Masui, H. Yamada, K. Iso, H. Hirasawa, N. N. Fellows, J. S. Speck, S. Nakamura, and S. P. DenBaars, Phys. Stat. Sol. (a) 205, 1203 (2008).
[21] M. Ueda, M. Funato, K. Kojima, Y. Kawakami, Y. Narukawa, and T. Mukai, Phys. Rev. B 78, 233303 (2008).
[22] H. Masui, H. Asamizu, T. Tyagi, N. F. DeMille, S. Nakamura, and S. P. DenBaars, Appl. Phys. Express 2, 071002 (2009).
[23] R. B. Chung, Y. D. Lin, I. Koslow, N. Pfaff, H. Ohta, J. Ha, S. P. DenBaars, and S. Nakamura, Jpn. J. Appl. Phys. 49, 070203 (2010).
[24] A. Tyagi, F. Wu, E. C. Young, A. Chakraborty, H. Ohta, R. Bhat, K. Fujito, S. P. DenBaars, S. Nakamura, and J. S. Speck, Appl. Phys. Lett. 95, 251905 (2009).
[25] Q. Yan, P. Rinke, M. Scheffler, and C. G. Van de Walle, Appl. Phys. Lett. 97, 181101 (2010).
[26] Y. Zhao, S. Tanaka, Q. Yan, C. Y. Huang, R. B. Chung, C-C. Pan, K. Fujito, D. Feezell, C. G. Van de Walle, J. S. Speck, S. P. DenBaars, and S. Nakamura, Appl. Phys. Lett. 99, 051109 (2011).

### CONCLUSION

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
a III-nitride based light emitting device grown on a semipolar (20-2-1) plane of a Gallium Nitride (GaN) substrate.

2. The device of claim 1, wherein the semipolar (20-2-1) plane of the Gallium Nitride substrate is inclined at approximately 15° towards a [000-1] direction from a nonpolar (10-10) plane.

3. The device of claim 1, wherein the semipolar (20-2-1) plane of the Gallium Nitride substrate is inclined at approximately 30° towards a [000-1] direction from a semipolar (20-21) plane.

4. The device of claim 1, wherein the III-nitride based light emitting device has a higher Indium uptake as compared to a III-nitride based light emitting device grown on polar, nonpolar or other semipolar planes.

5. The device of claim 1, wherein the III-nitride based N light emitting device has a higher polarization ratio as compared to a III-nitride based light emitting device grown on polar or other semipolar planes.

6. The device of claim 1, wherein the III-nitride based light emitting device has a similar polarization ratio as compared to a III-nitride based light emitting device grown on nonpolar planes.

7. A method of fabricating an optoelectronic device, comprising:
growing a III-nitride based light emitting device on a semipolar (20-2-1) plane of a Gallium Nitride (GaN) substrate.

8. The method of claim 7, wherein the semipolar (20-2-1) plane of the Gallium Nitride substrate is inclined at approximately 15° towards a [000-1] direction from a nonpolar (10-10) plane.

9. The method of claim 7, wherein the semipolar (20-2-1) plane of the Gallium Nitride substrate is inclined at approximately 30° towards a [000-1] direction from a semipolar (20-21) plane.

10. The method of claim 7, wherein the III-nitride based light emitting device has a higher Indium uptake as compared to a III-nitride based light emitting device grown on polar, nonpolar or other semipolar planes.

11. The method of claim 7, wherein the III-nitride based light emitting device has a higher polarization ratio as compared to a III-nitride based light emitting device grown on polar or other semipolar planes.

12. The method of claim 7, wherein the III-nitride based light emitting device has a similar polarization ratio as compared to a III-nitride based light emitting device grown on nonpolar planes.
